(19) United States
(12) Patent Application Publication
(10) Pub. No.: US 2006/0125385 A1
(43) Pub. Date: Jun. 15, 2006

(54) ACTIVE MATRIX ORGANIC ELECTRO-LUMINESCENCE DEVICE ARRAY AND FABRICATING PROCESS THEREOF

(76) Inventors: Chun-Chung Lu, Taichung County (TW); Shuenn-Jiun Tang, Hsinchu County (TW); Chih-Kwang Tzen, Pingtung County (TW); Jie-Huang Wu, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/905,087

(22) Filed: Dec. 14, 2004

(51) Int. Cl. H05B 33/00; H01J 1/62

(52) U.S. Cl. 313/506

(57) ABSTRACT

An active matrix organic electro-luminescence device array comprises an active element array substrate, a patterned rib, a conductive layer, an organic luminescent layer and a common electrode layer. The active element array substrate has a plurality of active elements, and the patterned rib is disposed over the active element array substrate, wherein the patterned rib has a plurality of apertures exposing the active elements. The conductive layer is disposed over the active element array substrate and the patterned rib, wherein a portion of the conductive layer disposed over the active element array substrate and a portion of the conductive layer disposed over the patterned rib are disconnected. The organic luminescent layer is disposed over the conductive layer in the apertures. Finally, for example, the common electrode layer is formed by a plasma diffusion method to cover the organic luminescent layer and the patterned rib completely and continuously.

### BACKGROUND OF THE INVENTION

1. Field of the Invention

The present invention relates to an organic electro-luminescence device array (OLED array) and fabricating process thereof. More particularly, the present invention relates to an active matrix organic electro-luminescence device array and fabricating process thereof.

2. Description of Related Art

Display apparatuses are the communication interface between people and information. Now the major display apparatuses are the flat panel display apparatuses. Flat panel display apparatuses can be divided into the following types, including organic electro-luminescence display apparatuses, plasma display panel (PDP) apparatuses, liquid crystal display (LCD) apparatuses, light emitting diode (LED), vacuum fluorescent display apparatuses, field emission display (FED) apparatuses and electro-chromatic display apparatuses, etc. Amongst all types of the flap panel display apparatuses, organic electro-luminescence display apparatus have many advantages, such as self-luminescence, wide view angle, energy-saving, simple manufacturing process, low production cost, low operation temperature, fast responsive speed and full-colors. With all the listed advantages, organic electro-luminescence display apparatuses are very likely to be the major flap panel display apparatuses in the near future.

FIG. 1 is a cross sectional view of a conventional organic electro-luminescence device array. Referring to FIG. 1, the organic electro-luminescence device array 100 comprises an active matrix array substrate 110, a patterned dielectric layer 120, a conductive layer 130, an organic luminescent layer 140 and a common electrode layer 150. The conventional fabricating process of the conductive layer 130 utilizes either a sputter process with a shadow mask or a photolithography process along with an etching process. Therefore, the fabricating process of the conductive layer 130 is very complicated and time-consuming and requires additional apparatuses, i.e. shadow masks or photo-masks, resulting in a high fabricating cost.

Additionally, the physical sputter process is utilized during the manufacture of the inverted top-emitting OLED to fabricate common electrode layer 150 over the organic luminescent layer 140 through deposition of films and the process requires high energy for ion bombardment, which will easily damage the organic luminescent layer 140 formed over the active matrix array substrate 110. As a result, the yield rate of the organic electro-luminescence device array 100 is reduced.

### SUMMARY OF THE INVENTION

Accordingly, the present invention is directed to an active matrix organic electro-luminescence device array capable of reducing the manufacturing cost and promoting the yield rate thereof.

The present invention is also directed to a fabricating process of an active matrix organic electro-luminescence device array capable of simplifying the manufacturing steps and promoting the yield rate thereof.

The present invention comprises an active matrix organic electro-luminescence device array. The active matrix organic electro-luminescence device array consists of an active element array substrate, a patterned rib, a conductive layer, an organic luminescent layer and a common electrode layer. The active element array substrate has a plurality of active elements. The patterned rib is disposed over the active element array substrate and it has a plurality of apertures, which expose the active elements. The conductive layer is disposed over the active element array substrate exposed by the apertures and is disposed over the patterned rib. Further, the portion of the conductive layer disposed over the active element array substrate and the portion of the conductive layer disposed over the patterned rib are not connected. The organic luminescent layer is disposed over the conductive layer in the apertures. The common electrode layer completely and continuously covers the organic luminescent layer and the patterned rib.

The common electrode layer of the active matrix organic electro-luminescence device array provides a complete coverage, which reduces consumption of electrical current and promotes the display efficiency of the active matrix organic electro-luminescence device array. Additionally, the patterned rib automatically disconnects the conductive layer of each pixel, hence simplifying the fabricating process.

A fabricating process of an active matrix organic electro-luminescence device array is provided. The fabricating process of an active matrix organic electro-luminescence device array comprises the following steps. First, a patterned rib is formed over an active element array substrate, wherein the active element array substrate has a plurality of active elements. The patterned rib has a plurality of apertures and the active elements are exposed by the apertures. Next, a conductive layer is formed over the active element array substrate exposed by the apertures and is formed over the patterned rib, wherein a portion of the conductive layer disposed over the active element array substrate and a portion of the conductive layer disposed over the patterned rib are not connected. Next, an organic luminescent layer is formed over the conductive layer in the apertures. Finally, a common electrode layer is formed, covering the organic luminescent layer and the patterned rib completely and continuously.

The fabricating process of an active matrix organic electro-luminescence device array utilizes the patterned rib and the fully covering common electrode layer to simplify the fabricating steps, promote the display efficiency, and reduce the power consumption.

### BRIEF DESCRIPTION OF THE DRAWINGS

FIG. 1 is a cross sectional view of a conventional organic electro-luminescence device array.

FIG. 2A is a cross sectional view of an active matrix organic electro-luminescence device array according to one embodiment of the present invention.

FIGS. 2B, 2C are top views of the meshed rib of an active matrix organic electro-luminescence device.

FIGS. 3A to 3E shows a fabricating process of an active matrix organic electro-luminescence device array according to one embodiment of the present invention.

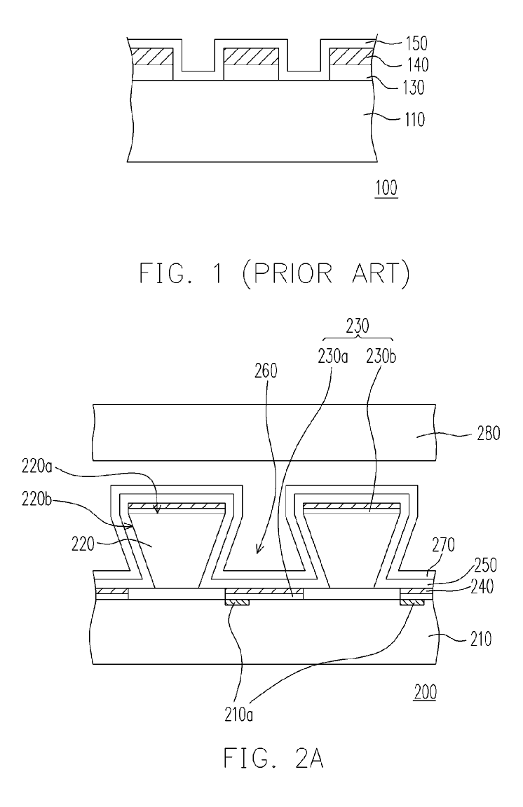

### DESCRIPTION OF THE EMBODIMENTS

Various specific embodiments of the present invention are disclosed below, illustrating examples of various possible implementations of the concepts of the present invention. The following description is made for the purpose of illustrating the general principles of the invention and should not be taken in a limiting sense. The scope of the invention is best determined by reference to the appended claims.

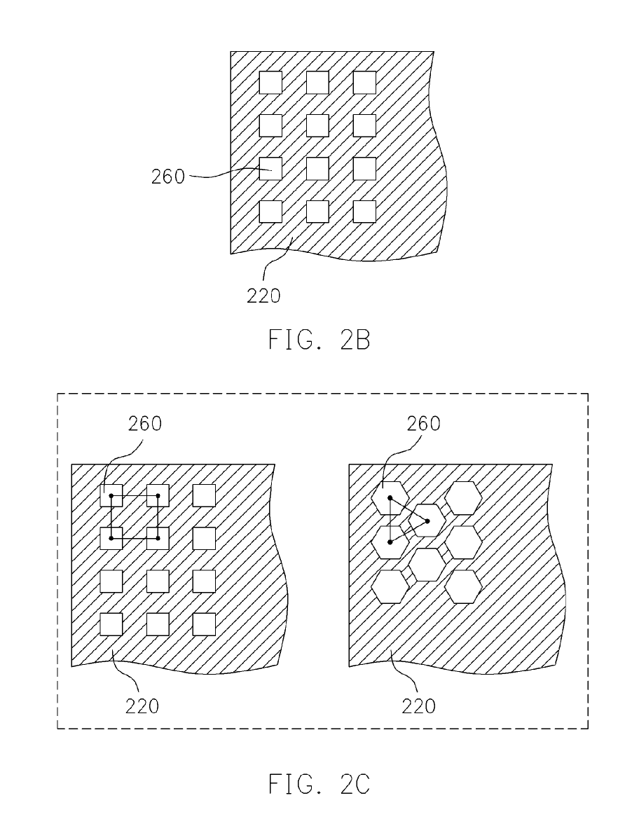

FIG. 2A is a cross sectional view of an active matrix organic electro-luminescence device array according to one embodiment of the present invention. Referring to FIG. 2A, the active matrix organic electro-luminescence device array 200 mainly comprises an active element array substrate 210, a patterned rib 220, a conductive layer 230, an organic luminescent layer 240 and a common electrode layer 250.

As shown in FIG. 2A, the active element array substrate 210 has a plurality of active elements 210a. Active elements 210a control the amount of electrical current passing through the organic luminescent layer 240 of each pixel in order to regulate the luminescent strength of the organic luminescent layer 240. In one embodiment, the active elements 210a are, for example, thin film transistors (TFT), which can promote the efficiency of display apparatuses. Undoubtedly, the active elements 210a can also be light emitting diodes or other active elements.

Referring to FIG. 2A, the patterned rib 220 having a plurality of apertures 260 is disposed over the active element array substrate 210, wherein the pattern of the patterned rib 220 can be meshed or striped. Each aperture 260 exposes at least one active element 210a. FIGS. 2B and 2C are top views of meshed rib of an active matrix organic electro-luminescence device. As shown in FIG. 2B, when the pattern of the patterned rib 220 is meshed, the shape of the aperture 260 can be quadrangle, triangle, hexagon, circle or other geometric shape. Additionally, as shown in FIG. 2C, the apertures 260 can be arranged in triangles or matrixes.

Referring to FIG. 2A, the conductive layer 230 is disposed over the active element array substrate 210 exposed by the aperture 260 and is disposed over the patterned rib 220. There is a height difference between the surface of the active element array substrate 210 exposed by the aperture 260 and the surface of the patterned rib 220, and the cross-section of the patterned rib 220 is an inverted trapezoid. As a result, when the conductive layer 230 is deposited through sputter or other common fabricating processes, the conductive materials will not cover the active element array substrate 210 continuously and the conductive layer 230 of each pixel will thus be electrically disconnected from one another. Therefore, no complicated fabricating processes, i.e. sputter, photolithography, or etching processes with shadow mask, will be utilized to fabricate the conductive layer230. In addition, the conductive layer 230a in each aperture 260(i.e. in each pixel) is electrically connected with the active element 210a exposed by the aperture 260. Thereby, the conductive layer 230a in each aperture 260 can be a pixel electrode of each pixel in the active matrix organic electro-luminescence device array 200.

Referring to FIG. 2A, the organic luminescent layer 240 is disposed over the conductive layer 230a in the aperture 260. It should be noted that the organic luminescent layer 240 and the patterned rib 220 are covered by the common electrode layer 250 continuously, that is, the organic luminescent layer 240 and the top surface 220a and the side surface 220b of the patterned rib 220 are covered by the common electrode layer 250 continuously.

As shown in FIG. 2A, the active matrix organic electro-luminescence device array 200 further comprises a protection layer 270 to cover the common electrode layer 250. The protection layer 270 can protect the fabricated active matrix organic electro-luminescence device array 200 from being damaged by outside pollutant or moisture in the atmosphere, ensuring the active matrix organic electro-luminescence device array 200 will function properly. In one embodiment, the active matrix organic electro-luminescence device array 200 further comprises a cover substrate 280 disposed over the active element array substrate 210. Wherein the organic luminescent layer 240 is sealed between the active element array substrate 210 and the cover substrate 280 to protect the active matrix organic electro-luminescence device array 200 from damages. Certainly, the active matrix organic electro-luminescence device array 200 can utilize the protection layer 270 or the cover substrate 280 or both of them.

The kind of materials utilized in each layer determines whether the active matrix organic electro-luminescence device array 200 to emit light without heat in one direction or in two directions. Referring to FIG. 2A, in one embodiment, the active element array substrate 210 and other layers utilize, for example, the light transparent materials, thereby the luminescence is emitted from the front and the back of the active element array substrate 210, i.e. luminescence in two directions. However, if one layer of the active element array substrate 210 or that of other layers utilizes non-transparent materials, the active element array substrate 210 will only luminesce in one direction.

In one embodiment, the materials of the conductive layer 230 and the common electrode layer 250 are, for example, metals, metal oxide or metal oxynitride. More specifically, the materials of the conductive layer 230 and the common electrode layer 250 can be indium tin oxide (ITO), indium zinc oxide (IZO) or other transparent conductive materials. Certainly either the conductive layer 230 or the common electrode layer 250 can also utilize the non-transparent conductive materials. The materials of the organic luminescent layer 240 include organic luminescent materials that can emit red, blue or green lights. The materials of the common electrode layer 250 include transparent conductive materials, such as indium tin oxide (ITO) or indium zinc oxide (IZO).

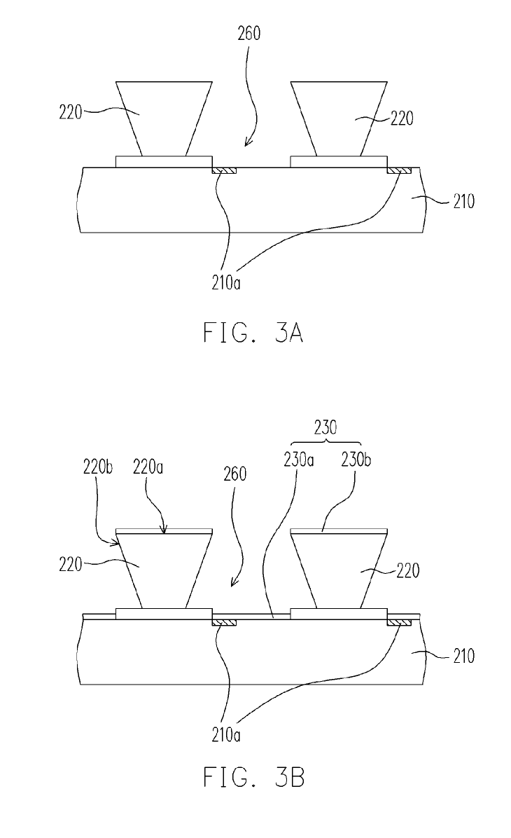

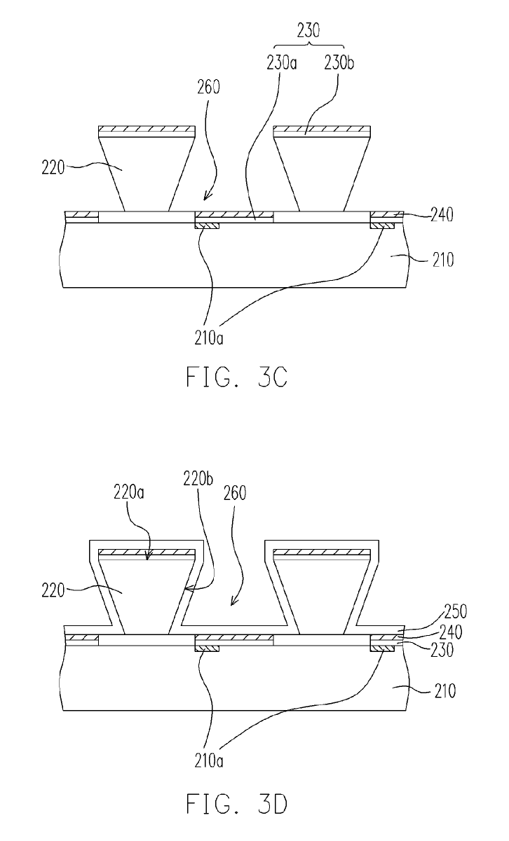

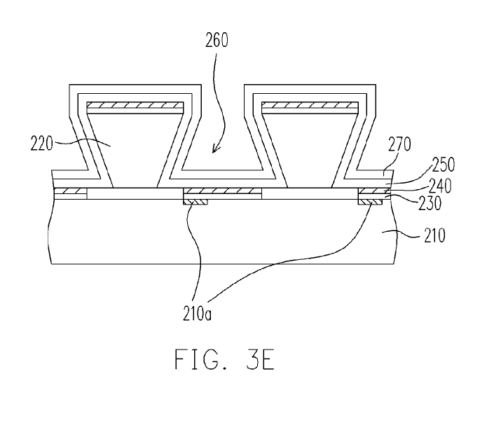

FIGS. 3A to 3E shows a fabricating process of an active matrix organic electro-luminescence device array according to one embodiment of the present invention.

Referring to FIG. 3A, a patterned rib 220 is formed over the active element array substrate 210, wherein the active element array substrate 210 has a plurality of active elements 210a, and the patterned rib 220 has a plurality of apertures 260 exposing the active elements 210a. In one embodiment, the patterned rib 220 is, for example, formed over the active element array substrate 210 by a simplified photolithography fabricating process. Due to a height difference between the surface of the active element array substrate 210 exposed by the aperture 260 and the surface of the patterned rib 220, and the cross section of the patterned rib 220 is an inverted trapezoid, a plurality of pixel of the organic electro-luminescence device can be defined by the patterned rib 220.

As shown in FIG. 3B, a conductive layer 230 is formed over the active element array substrate 210 exposed by the aperture 260 and is formed over the patterned rib 220. In one embodiment, when the conductive layer 230 is deposited by the sputter or other film deposition processes, a conductive layer 230 cannot be formed over the active element array substrate 210 continuously, because the cross section of the patterned rib 220 is an inverted trapezoid, and there is a height difference between the surface of the active element array substrate 210 exposed by the aperture 260 and the surface of the patterned rib 220. As a result, electrically disconnected pixel electrodes 230a will be formed in the apertures 260. Therefore, as shown in FIG. 3B, a portion 230a of the conductive layer 230 formed over the active element array substrate 210 and a portion 230b of the conductive layer 230 formed over the patterned rib 220 are disconnected from one another.

As shown in FIG. 3C, an organic luminescent layer 240 is formed on the conductive layer 230a in the aperture 260. When electrical currents pass from the conductive layer 230a to the organic luminescent layer 240, the electro-luminescent effect will occur. In some fabricating process, although an organic luminescent layer 240 is formed over the patterned rib 220, the luminescent effect will not be influenced.

As shown in FIG. 3D, a common electrode layer 250 is formed over the organic luminescent layer 240 and the patterned rib 220. That is, a common electrode layer 250 is deposited over the organic luminescent layer 240 and the top surface 220a and the lateral surface 220b of the patterned rib 220. In one embodiment, the common electrode layer 250 is fabricated by, for example, a plasma diffusion process, i.e. ions are formed from the electrode materials by plasma and the ions are then diffused into the organic luminescent layer 240 over the active element array substrate 210 and the top surface 220a and the lateral surface 220b of the patterned rib 220, in order to form a continuous common electrode layer 250. The plasma diffusion process utilized in the present invention is very different from the conventional sputter process or other film deposition processes that it has advantages, i.e. a film can be formed continuously over the discontinuity structure by the plasma diffusion process. With the utilization of the plasma diffusion process, large-scaled deposition of the conductive film can be achieved and the fabricated conductive film has a lower resistance and higher flatness. Therefore, the electrical connection between the conductive films will be enhanced and the efficiency of currents utilized will be promoted.

Additionally, due to the lower operation temperature employed by the plasma diffusion process, the organic luminescent layer 240 disposed over the active element array substrate 210 will not be damaged. In one embodiment, the temperature around the organic luminescent layer 240 may be lower than 80 degrees centigrade during the plasma diffusion process for deposition of the common electrode layer 250. Because the organic luminescent layer 240 disposed over the active element array substrate 210 will not be damaged under the foregoing temperature, the yield rate of the active matrix organic electro-luminescence device array 200 will be promoted.

As shown in FIG. 3E, after the formation of the common electrode layer 250, a protection layer 270 will be formed on top of the common electrode layer 250. The protection layer 270 can prevent the active matrix organic electro-luminescence device array 200 from being damaged by pollutant or moisture in the atmosphere, ensuring the active matrix organic electro-luminescence device array 200 will function properly. In one embodiment, the protection layer 270 can also be fabricated into a complete and continuous film by the plasma diffusion process to enhance its protecting effect.

Referring to FIG. 2A, in another embodiment, a cover substrate 280 can be disposed over the active element array substrate 210. Further, the luminescent layer 240 is sealed between the active element array substrate 210 and the cover substrate 280. Thereby the active matrix organic electro-luminescence device array 200 will be prevented from damages by external force and moisture in the atmosphere.

To sum up, the present invention, i.e. the active matrix organic electro-luminescence device array and fabricating process thereof, has at least the following advantages, but not limited thereto.

(1) The conductive layer can be divided automatically into two portions by the patterned rib, i.e. one portion disposed over the active element array substrate and another portion disposed over the patterned rib. Thereby the fabricating process of the active matrix organic electro-luminescence device array can be simplified and the fabricating cost thereof can also be reduced.

(2) Because the common electrode layer is fabricated by a plasma diffusion process of the present invention, a film can be continuously formed to cover the surface of the organic electro-luminescence device. In addition, the operation temperature is lower than that of the conventional fabricating process, ensuring the organic luminescent layer will not be damaged and the yield rate of the active matrix organic electro-luminescence device array will be promoted.

The above description provides a full and complete description of the preferred embodiments of the present invention. Various modifications, alternate construction, and equivalent may be made by those skilled in the art without changing the scope or spirit of the invention. Accordingly, the above description and illustrations should not be constructed as limiting the scope of the invention, which is defined by the following claims.

What is claimed is:

1. An active matrix organic electro-luminescence device array, comprising:
an active element array substrate having a plurality of active elements;
a patterned rib disposed over the active element array substrate, wherein the patterned rib has a plurality of apertures and the active elements are exposed by the apertures;
a conductive layer disposed over the active element array substrate exposed by the apertures and over the patterned rib, wherein a portion of the conductive layer disposed over the active element array substrate and a portion of the conductive layer disposed over the patterned rib are disconnected;
an organic luminescent layer disposed over the conductive layer in the apertures; and
a common electrode layer covering the organic luminescent layer and the patterned rib continuously.

2. The active matrix organic electro-luminescence device array of claim 1, wherein the patterned rib comprises a meshed rib.

3. The active matrix organic electro-luminescence device array of claim 1, wherein the patterned rib comprises a striped rib.

4. The active matrix organic electro-luminescence device array of claim 1, wherein a material of the common electrode layer comprises a transparent conductive material.

5. The active matrix organic electro-luminescence device array of claim 4, wherein the material of the common electrode layer comprises indium tin oxide (ITO) or indium zinc oxide (IZO).

6. The active matrix organic electro-luminescence device array of claim 1, wherein a material of the common electrode layer comprises metal, metal oxide, metal nitride, or metal oxynitride.

7. The active matrix organic electro-luminescence device array of claim 1, wherein a material of the conductive layer comprises a transparent conductive material.

8. The active matrix organic electro-luminescence device array of claim 7, wherein the material of the conductive layer comprises indium tin oxide (ITO) or indium zinc oxide (IZO).

9. The active matrix organic electro-luminescence device array of claim 1, wherein a material of the conductive layer comprises metal, metal oxide, metal nitride, or metal oxynitride.

10. The active matrix organic electro-luminescence device array of claim 1, wherein the active element array substrate is light transparent.

11. The active matrix organic electro-luminescence device array of claim 1, further comprising a protection layer covering the common electrode layer.

12. The active matrix organic electro-luminescence device array of claim 1, further comprising a cover substrate disposed over the active element array substrate, wherein the organic luminescent layer is sealed between the active element array substrate and the cover substrate.

13. A fabricating process of an active matrix organic electro-luminescence device array, comprising:
forming a patterned rib over an active element array substrate, wherein the active element array substrate has a plurality of active elements, and wherein the patterned rib has a plurality of apertures and the active elements are exposed by the apertures;
forming a conductive layer over the active element array substrate exposed by the apertures and over the patterned rib, wherein a portion of the conductive layer disposed over the active element array substrate and a portion of the conductive layer disposed over the patterned rib are disconnected;
forming an organic luminescent layer over the conductive layer in the apertures; and
forming a common electrode layer covering the organic luminescent layer and the patterned rib continuously.

14. The fabricating process of an active matrix organic electro-luminescence device array of claim 13, wherein the step of forming the common electrode layer comprises a plasma diffusion process.

15. The fabricating process of an active matrix organic electro-luminescence device array of claim 13, wherein the organic luminescent layer is at an operation temperature less than 80 degrees centigrade while the common electrode layer is formed.

16. The fabricating process of an active matrix organic electro-luminescence device array of claim 13, further comprising a step of forming a protection layer over the common electrode layer after the common electrode layer is formed.

17. The fabricating process of an active matrix organic electro-luminescence device array of claim 13, further comprising a step of disposing a cover substrate over the active element array substrate after the common electrode layer is formed, wherein the organic luminescent layer is sealed between the active element array substrate and the cover substrate.
